(19) United States
(12) Patent Application Publication
(10) Pub. No.: US 2008/0089044 A1
(43) Pub. Date: Apr. 17, 2008

(54) Spacer block for rebuilt electrically operated automatic transmission controller assembly

(75) Inventors: Paul Fathauer, Sullivan, IN (US); Darrell Bates, Bicknell, IN (US); Terry Fuller, Muscle Shoals, AL (US); Jimmy Fuller, Muscle Shoals, AL (US)

Correspondence Address: KRIEG DEVAULT LLP, ONE INDIANA SQUARE, SUITE 2800, INDIANAPOLIS, IN, 46204-2079, US

(73) Assignee: Raybestos Powertrain, LLC

(21) Appl. No.: 11/581,706

(22) Filed: Oct. 16, 2006

(51) Int. Cl. H05K 7/10

(52) U.S. Cl. 361/768

(57) ABSTRACT

A spacer block that provides for a method of rebuilding an electrically operated automatic transmission controller assembly is disclosed. The block allows for offsetting and stabilizing or securing a printed circuit (PC) board to a manifold block, in which several solenoid assemblies reside within the span of the spacer block. The spacer block includes a first means for connecting to the manifold block and a second means for connecting to the PC board. The rebuilt solenoid module preferably includes at least one new solenoid.

### BACKGROUND

The present invention relates to a fluid control device comprising one or more actuators, or solenoids, arranged and secured within a manifold block. Such a fluid control device constitutes a solenoid block module that finds use, for example, in automatic transmissions used in motor vehicles.

Within the field of the automotive aftermarket, there are numerous devices that are considered to be “non-serviceable” items. In such cases, a new assembly must be purchased at a substantial cost to the end user. One such assembly is described in U.S. Pat. No. 4,678,006 to Northman et al. titled “Electrically Operated Automatic Transmission Controller Assembly”. This assembly is identically described in related divisional U.S. Pat. No. 4,783,049 to Northman et al. also titled “Electrically Operated Automatic Transmission Controller Assembly”. In the assembly described therein, five electrically actuated solenoid assemblies are situated on an aluminum manifold block consisting of multiple fluid passageways. The solenoid assemblies are interconnected via a Printed Circuit board (hereinafter referred to as a “PC board”) to a terminal connector consisting of numerous pins that connect through a wire harness to an electronic automatic transmission controller.

Due to the configuration of the PC board and terminal connector, attempts at servicing devices such as those disclosed in U.S. Pat. No. 4,678,006 have had less than optimal results. In fact, the assembly of U.S. Pat. No. 4,678,006 is explicitly referred to as having been designed as a unitary subassembly and designed to prevent unauthorized attempts at servicing and/or otherwise prevent tampering (see Abstract, Background Of the Invention, and Summary Of The Invention sections of U.S. Pat. No. 4,678,006). Thus, intrinsic aspects of the design of the module make servicing difficult.

### SUMMARY

In one embodiment there is a spacer block for stabilizing or mechanically retaining a printed circuit board of a rebuilt solenoid module, the rebuilt solenoid block module further including a manifold block and a spacer plate. The spacer block comprises a main body extending between a first end and a second end. The first end includes first means for connecting to the manifold block. The second end includes second means for connecting to the printed circuit board.

In one refinement of an embodiment the first means for connecting comprises an external threaded portion extending from the first end of the main body.

In another refinement of an embodiment the second means for connecting comprises an internally threaded bore in the second end extending toward the first end. The bore is sized to receive a threaded fastener passing through an orifice in the printed circuit board.

In another refinement of an embodiment a portion of the main body adjacent the second end has a hexagonal cross section and a portion of the main body adjacent the first end has a substantially circular cross-section.

In another refinement of an embodiment the main body has a length of about 1.160 inches.

In another refinement of an embodiment the second means for connecting at is a snap fit means for connecting.

In another refinement of an embodiment the snap fit means for connecting includes a plurality of flanges extending from the second end in a direction away from the first end.

In another refinement of an embodiment each flange defines a portion of an arc of a circle. The flanges each having a first portion with a first outer diameter adjacent the second end and a second portion with a second outer diameter. The second outer diameter is larger than the first outer diameter.

In another refinement of an embodiment the second outer diameter is greater than the first outer diameter by 0.001 to 0.05 inches, and wherein the main body has a length of about 1.160 inches.

In another refinement of an embodiment the first means for connecting comprises an external threaded portion extending from the first end of the main body. The second means for connecting comprises an internally threaded bore in the second end extending toward the first end. The bore is sized to receive a fastener passing through an orifice in the printed circuit board, wherein the main body has a length of about 1.160 inches.

In another embodiment of the invention there is a rebuilt solenoid module. The module comprises a manifold block and a plurality of solenoids received in a plurality of corresponding solenoid openings in the manifold block. At least one of the solenoids is a new solenoid. The module further comprises a spacer plate abutting at least a portion of the manifold block, the spacer plate also including a plurality of solenoid openings. The module further comprises a terminal connector inserted through a terminal connector opening in the spacer plate. The module further comprises a plurality of spacer blocks. Each spacer block has a main body extending between a top end and a bottom end, at least a portion of the bottom end being connected to the manifold block. The module further comprises a printed circuit board soldered to at least one electrical connection on each of the plurality of solenoids. The printed circuit board is connected to the top end of at least one of the plurality of spacer blocks.

In one refinement of an embodiment the at least one of the plurality of spacer blocks is not integrally formed with other components of the rebuilt solenoid module.

In another refinement of an embodiment the printed circuit board is an unencapsulated printed circuit board.

In another refinement of an embodiment all of the plurality of solenoids are new solenoids.

In another refinement of an embodiment the bottom end of each spacer block includes first means for connecting to the manifold block.

In another refinement of an embodiment the first means for connecting to the manifold block comprises a threaded portion extending from the bottom end of the main body.

In another refinement of an embodiment the top end of each spacer block includes second means for connecting to the printed circuit board.

In another refinement of an embodiment the second means for connecting is a snap fit means for connecting.

In another refinement of an embodiment the snap fit means for connecting includes a plurality of flanges extending upward from a top surface of the top end of the spacer block.

In another refinement of an embodiment each flange defines a portion of an arc of a circle. The flanges each have a first portion with a first outer diameter adjacent the top surface of the second end and a second portion with a second outer diameter. The second outer diameter is larger than the first outer diameter. The first outer diameter of the flanges of the spacer block is about the same as the diameter of the orifice in the printed circuit board. The second outer diameter is greater than the first outer diameter by 0.001 to 0.05 inches.

In another refinement of an embodiment the second means for connecting comprises a bore in the top end of each spacer block extending through at least a portion of the main body toward the bottom end of each spacer block. The top end of the spacer block and the printed circuit board are connected via a fastener passing through the spacer block orifice in the printed circuit board and inserted into the bore at the top end of the spacer block.

In another refinement of an embodiment a portion of the spacer block contacts a top surface of the spacer plate and holds the spacer plate against the manifold block.

In yet another embodiment there is a rebuilt solenoid module. The module comprises a manifold block and a plurality of solenoids received in a plurality of corresponding solenoid holes in the manifold block. The module further comprises a spacer plate contacting at least a portion of the manifold block, the spacer plate also including a plurality of solenoid holes. The module also comprises a terminal connector inserted through a terminal connector hole in the spacer plate. The module further comprises a plurality of spacer blocks. Each spacer block has a main body extending between a first end and a second end. The first end of at least one spacer block including first means for connecting the spacer block to the manifold block. The module further comprises a printed circuit board soldered to at least one electrical connection on each of the plurality of solenoids. The printed circuit board has a plurality of spacer block orifices. The printed circuit board is connected to a second means for connecting at the second end of each spacer block through the respective one of the plurality of spacer block orifices.

In one refinement of an embodiment the printed circuit board is an unencapsulated printed circuit board.

In another refinement of an embodiment at least one of the plurality of solenoids is a new solenoid.

In another refinement of an embodiment the first means for connecting and the second means for connecting include a single fastener extending through a passage defined between the first end and the second end of each spacer block.

In another refinement of an embodiment the fastener is a bolt having an externally threaded end that passes through each spacer block orifice of the unencapsulated printed circuit board and through the second end of the spacer block and out the first end. The externally threaded end of the bolt is installed into a corresponding internally threaded spacer block opening in the manifold block.

In another refinement of an embodiment a portion of the spacer block contacts a top surface of the spacer plate and holds the spacer plate against the manifold block.

### BRIEF DESCRIPTION OF THE DRAWINGS

FIG. 1 is a perspective view of one embodiment of a spacer block.

FIG. 2 is a top view of the spacer block of FIG. 1.

FIG. 3 is a cross-sectional view of the spacer block of FIG. 2 along the lines 3-3.

FIG. 4 is a detailed view of the portion of the spacer block of FIG. 3 along the line(s) 4-4.

FIG. 5 is a perspective view of another embodiment of a spacer block.

FIG. 6 is a top view of the spacer block of FIG. 5.

FIG. 7 is a partial cross-sectional view of the spacer block of FIG. 5.

FIG. 8 is a perspective view of another embodiment of a spacer block.

FIG. 9 is a top view of the spacer block of FIG. 8.

FIG. 10 is a side view of the spacer block of FIG. 8.

FIG. 11 is a sectional view along the line 11-11 of the spacer block of FIG. 10.

FIG. 12 is a top view of the base manifold component of a solenoid module.

FIG. 13 is a top view of the base manifold component of FIG. 12 after being combined with a plurality of solenoids and a spacer plate.

FIG. 14 is a top view of the solenoid module components of FIG. 13 with the addition of a plurality of spacer blocks and a terminal connector.

FIG. 15 is a side perspective view of one embodiment of an assembled solenoid module.

FIG. 16 is a side sectional view of an aspect of the prior art solenoid module.

FIG. 17 is a side sectional view of the spacer block of the present invention holding the spacer plate against the base manifold prior to transmission installation.

### DESCRIPTION OF THE ILLUSTRATIVE EMBODIMENTS

For purposes of promoting an understanding of the principles of the invention, reference will now be made to the embodiments illustrated in the drawings and specific language will be used to describe the same. It will nevertheless be understood that no limitation of the scope of the invention is thereby intended, such alterations and further modifications in the illustrated device, and such further applications of the principles of the invention as illustrated therein being contemplated as would normally occur to one skilled in the art to which the invention relates.

As previously noted, the present invention relates to a solenoid block module that finds use, for example, in automatic transmissions used in motor vehicles. More particularly, various embodiments of the present invention relate to a spacer block that can be used for servicing or rebuilding such a solenoid block module. Historically, the complete solenoid block assembly must be replaced if one or more defects exist. In addition, many service technicians replace the entire solenoid block module during a complete rebuild of the transmission. Many times this is done even if the solenoid block module is operational. However, because the remaining life of the existing solenoid block module cannot be accurately predicted with normal shop tools, service professionals will minimize the risk of solenoid block module failure within the rebuild warranty period by replacing the entire unit. This practice can increase the cost of a rebuild by $200-300 depending on the vehicle.

A major obstacle to the servicing of a solenoid block assembly is the inability to reuse the original encapsulated PC board because of damage during the removal process. Other obstacles include the unavailability of replacement solenoids, terminal connectors and PC boards. For example, the original PC board of the solenoid block assembly of U.S. Pat. No. 4,678,006 to Northman et al. is an encapsulated (“overmolded”) design, in which a thermoplastic case is molded over the PC board. Even though such a design is costly, it provides for automated assembly of the solenoid block assembly. The remanufacturing process, however, is principally a manually intensive process and difficult to automate. Thus, the present inventors have concluded that use of the encapsulated PC board design provides little to no advantage to the rebuilder. Therefore, it should be understood that the design used in conjunction with embodiments of the present invention is preferably a PC board without encapsulation. Absent any connection provided by the thermoplastic case in prior art assemblies such as U.S. Pat. No. 4,678,006, there is no direct connection of the PC board to the manifold block. Consequently, the PC board is only secured by the soldered connections of the board and the solenoids and terminal connector. This can lead to premature failures at the soldered joints because of stress from vibration and heat. Therefore, there is a desire for a device that allows for the use of PC boards without an encapsulated case while preventing or minimizing premature failure of the (soldered) connections between various components of the solenoid block module.

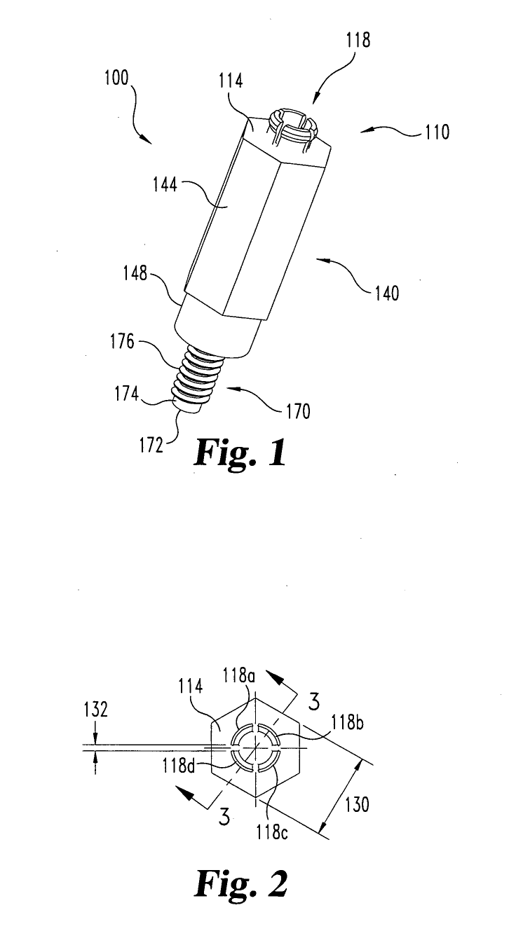

With reference to FIGS. 1-4 there is illustrated one embodiment of a spacer block of the present invention. Spacer block 100 has a main body 140 extending between top end 110 and bottom end 170. The main body 140 has a preferably hexagonal portion 144 substantially adjacent to top end 110. Main body 140 also preferably has a substantially cylindrical portion 148 adjacent to bottom end 170.

It should be understood that portion 144 of main body 140 may have a cross-section other than hexagonal. Such cross-sectional shape is selected for ease of assembly (i.e. shaped to match the head of a wrench for rotation of the spacer block, or for ease of grasping for rotation by hand). Persons of ordinary skill in the art will understand that a wide variety of cross-sectional shapes corresponding to various wrench heads are contemplated as within the scope of the invention. With reference to FIG. 2, in one embodiment the hexagonal portion 144 has a size 130 that preferably is about a 0.433 inch hex head (to fit a 7/16 inch socket). Similarly, cylindrical portion 148 corresponds to circular openings of the spacer plate (not illustrated in FIGS. 1-4). It is contemplated as within the scope of the invention that portion 148 may have other cross-sectional shapes, however such shapes should conform to openings in the spacer plate.

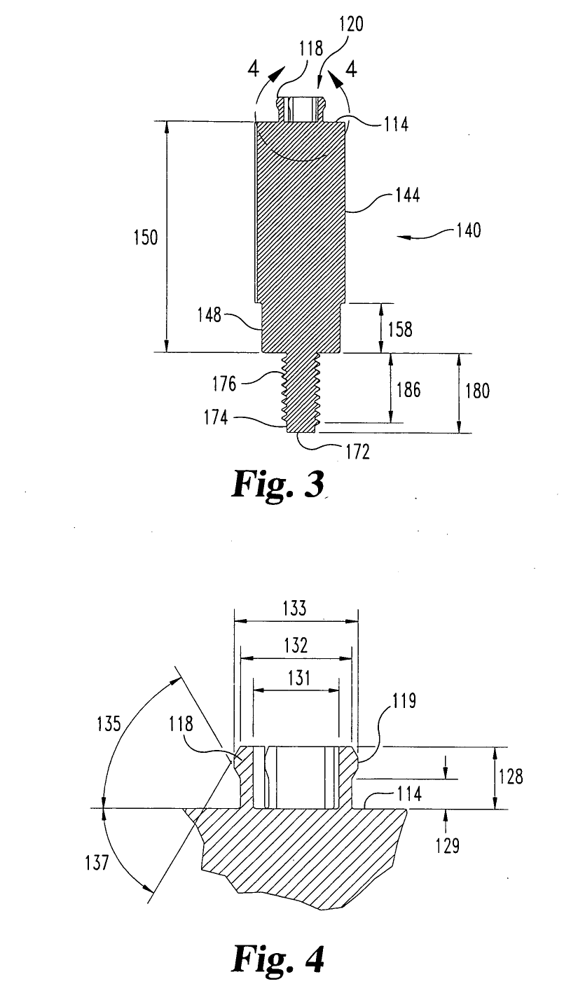

The bottom end 170 terminates in a tip 172 adjacent to unthreaded portion 174 that is adjacent to threaded portion 176. The threaded portion 176 of bottom end 170 is substantially adjacent to the cylindrical portion 148 of main body 140. The threaded portion 176 of bottom end 170 secures the spacer block 100 to a threaded hole in the manifold block (not illustrated in FIGS. 1-4). With reference to FIG. 3, the bottom end 170 has a length 180 that is preferably about 0.400 inches. The threaded portion 176 preferably has 10-24 threads that extend away from main body 140 for a length 186 that is preferably about 0.350 inches. It should be understood that it is contemplated as within the scope of the invention that the threading might extend all the way to the tip 172 of bottom end 170.

Top end 110 is intended to be secured to a PC board (not illustrated in FIGS. 1-4) that preferably rests atop at least a portion of top surface 114 of end 110. In the embodiment of FIGS. 1-4, the PC board is preferably secured to the spacer block 100 via snap fit means for connecting 120 the spacer block 100 to an opening in the PC board. In one embodiment, the snap fit means for connecting 120 preferably comprises a plurality of flanges 118. The flanges 118 are preferably integrally formed with spacer block 100 and extend upward from top surface 114 of top end 110. In the illustrated embodiment there are four flanges 118a, 118b, 118c and 118d for connecting the spacer block 100 to a PC board. It should be understood that greater and lesser numbers of flanges are contemplated as within the scope of the invention. With reference to FIG. 2, in one embodiment the flanges 118 are spaced apart from one another by a distance 132 that preferably is about 0.030 inches.

With reference to FIG. 3, in one embodiment the main body 140 of spacer block 100 extends for a distance 150 (from the top surface 114 to the beginning of the threaded portion 176 of bottom end 170) that is preferably about 1.160 inches, with the cylindrical portion 148 having a length 158 that is preferably about 0.250 inches.

With reference to FIG. 4, further detail concerning one embodiment of the snap fit means for connecting 120 is illustrated therein. Flanges 118 extend upward from top surface 114 by a length 128 that is preferably about 0.125 inches, with the lower narrower portion of the flange 118 having a length 129 that is preferably about 0.060 inches. The upper part of flanges 118 includes an oversized portion 119 having exterior surfaces that are angled at angles 135 and 137, the angles 135 and 137 preferably both being about sixty degrees. The inner width 131 of the flanges 118 is preferably about 0.170 inches. The middle width 132 of the lower narrower portion of flange 118 is preferably about 0.220 inches. The outer width 133 of the upper (oversized) portion 119 of flange 118 is preferably about 0.245 inches. As is illustrated, the flanges 118 are preferably arcs of a circle so that inner, middle and outer widths 131, 132, and 133 preferably correspond to internal, middle and outer diameters of the flanges 118. It will be understood by those of ordinary skill in the art that these diameters should at least loosely correspond to those present in the PC board. Thus, for these exemplary dimensions, the 0.245 inch outer diameter 133 of the oversized portion 119 is larger than the bore diameter of the opening in the PC board. The bore diameter of the opening in the PC board is preferably about the same size as the middle diameter 132. Thus, the flanges 118 should snap into the bore opening of the printed circuit board and provide mechanical support for stabilizing and/or retaining the PC board. The printed circuit board is retained on the top surface 114 of spacer block 100 by the oversized portion 119 of flange 118 that is larger than the bore diameter of the opening in the printed circuit board. In the exemplary diameters just discussed, the oversized portion 119 of flange 118 has a diameter 133 (0.245 inches) that is 0.025 inches larger than the bore diameter (0.220 inches) of the printed circuit board. The oversized portion 119 of flange 118 preferably has a diameter between 0.001 to 0.050 inches larger than the diameter of the opening in the PC board.

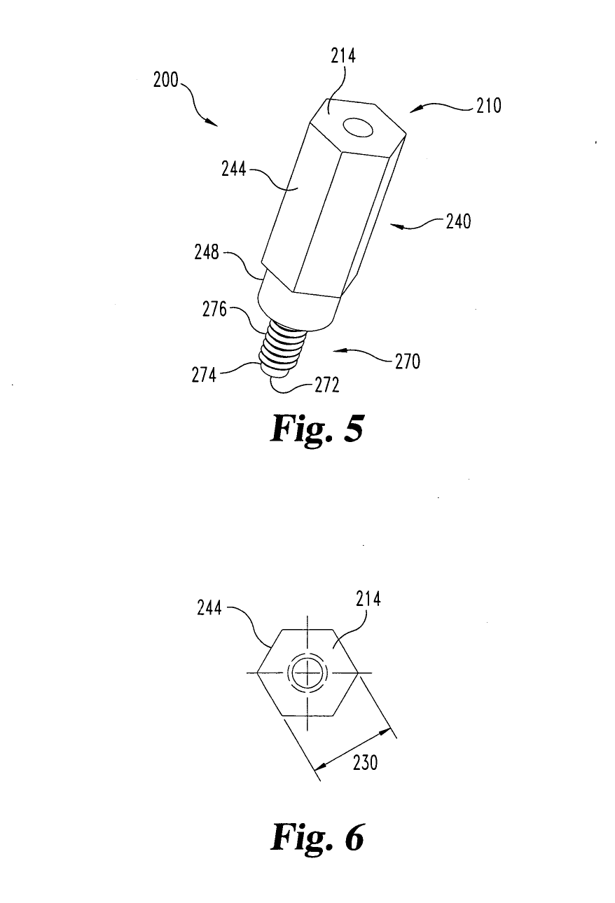

With reference to FIGS. 5-7 there is illustrated another embodiment of a spacer block of the present invention. Spacer block 200 has a main body 240 extending between top end 210 and bottom end 270. The main body 240 has a preferably hexagonal portion 244 substantially adjacent to top end 210. Main body 240 also preferably has a substantially cylindrical portion 248 adjacent to bottom end 270.

It should be understood that portion 244 of main body 240 may have a cross-section other than hexagonal. Such cross-sectional shape is selected for ease of assembly (i.e. shaped to match the head of a wrench for rotation of the spacer block, or for ease of grasping for rotation by hand). Persons of ordinary skill in the art will understand that a wide variety of cross-sectional shapes corresponding to various wrench heads are contemplated as within the scope of the invention. With reference to FIG. 6, in one embodiment the hexagonal portion 244 has a size 230 that preferably is about a 0.433 inch hex head (to fit a 7/16 inch socket). Similarly, cylindrical portion 248 corresponds to circular openings of the spacer plate (not illustrated in FIGS. 5-7). It is contemplated as within the scope of the invention that portion 248 may have other cross-sectional shapes, however such shapes should conform to openings in the spacer plate.

The bottom end 270 terminates in a tip 272 adjacent to unthreaded portion 274 that is adjacent to threaded portion 276. The threaded portion 276 of bottom end 270 is substantially adjacent to the cylindrical portion 248 of main body 240. The threaded portion 276 of bottom end 270 secures the spacer block 200 to a threaded hole in the manifold block (not illustrated in FIGS. 5-7). With reference to FIG. 7, the bottom end 270 has a length 280 that is preferably about 0.400 inches. The threaded portion 276 preferably has 10-24 threads that extend away from main body 240 for a length 286 that is preferably about 0.350 inches. It should be understood that it is contemplated as within the scope of the invention that the threading might extend all the way to the tip 272 of bottom end 270.

Top end 210 is intended to be secured to a PC board (not illustrated in FIGS. 5-7) that preferably rests atop at least a portion of top surface 214 of end 210. With reference to FIG. 7, in the embodiment of FIGS. 5-7, the PC board is preferably secured to the spacer block 200 via a fastener (see FIG. 15) with external screw threading that corresponds to the internal threading 222 of hole 220 in the top surface 214 of top end 210 of spacer block 200. The bottom portion of hole 220 preferably includes an unthreaded portion 224. The internal threading 222 of hole 220 is preferably 10-24 threading. It should be understood that it is contemplated as within the scope of the invention that, instead of being threaded, the hole 220 might be grooved or similarly roughened. Any of threads, grooves or roughening might permit the use of alternative fasteners, such as a fastener with a unidirectional barbed section to be inserted into the hole 220.

Further referring to FIG. 7, in one embodiment the main body 240 of spacer block 200 extends for a distance 250 (from the top surface 214 to the beginning of the threaded portion 276 of bottom end 270) that is preferably about 1.160 inches, with the cylindrical portion 248 having a length 258 that is preferably about 0.250 inches. The hole 220 preferably has a diameter of about 0.190 inches and the depth of the hole is preferably about two to three diameters deep.

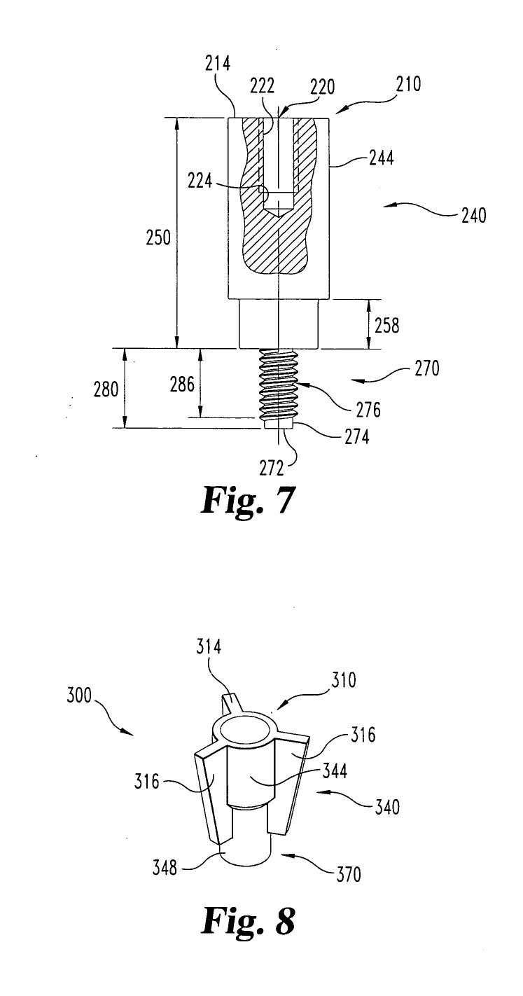

With reference to FIGS. 8-11 there is illustrated another embodiment of a spacer block of the present invention. Spacer block 300 has a main body 340 extending between top end 310 and bottom end 370. The main body 340 has a first cylindrical portion 344 beginning at top end 310 and a second substantially cylindrical portion 348 at bottom end 370. First cylindrical portion 344 preferably includes a plurality of fins 316 that are tapered from the top end 310 down toward and extending onto the second substantially cylindrical portion 348. Fins 316 terminate prior to reaching bottom end 370. Cylindrical portion 348 corresponds to circular openings of the spacer plate (not illustrated in FIGS. 8-11). It is contemplated as within the scope of the invention that second portion 348 may have other cross-sectional shapes, however such shapes should conform to openings in the spacer plate.

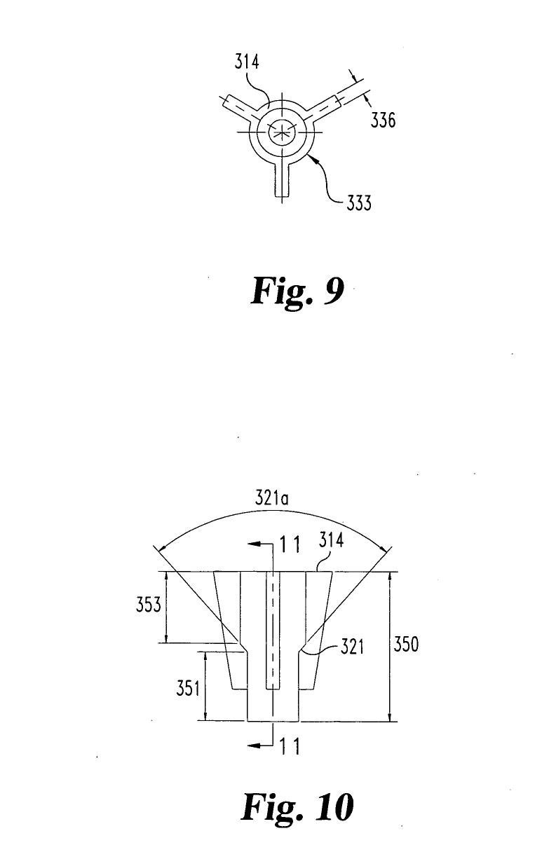

With reference to FIG. 9, the fins 316 of first cylindrical portion 344 have a thickness 336 that is preferably about 0.100 inches. Ignoring fins 316, first cylindrical portion 344 of main body 340 has a circular cross-section with an outer diameter 333 of about 0.500 inches.

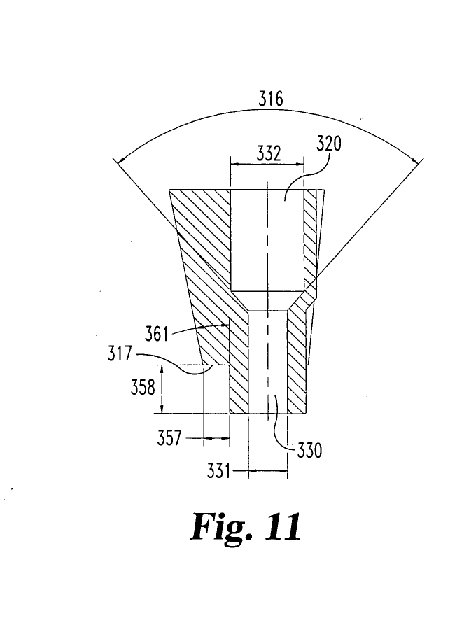

With reference to FIGS. 10 and 11, further exemplary dimensions and aspects of this embodiment are illustrated. Referring to FIG. 10, the transition from first portion 344 to second portion 348 occurs at taper 321 that has an angle 321a of about eighty-two degrees. It should be understood, however, that the taper 321 is completely optional, and indeed is not required when the bolt head rests on the PC board and the bolt extends through the bore 330 and threads into the manifold block. Moreover, as the taper is optional in such a configuration, the bores 320 and 330 of differing diameters 332 and 331, respectively, are preferably a single bore (extending the length 350 of the spacer block 300) having the diameter 331 of the bore 330.

However, it should also be understood that it is contemplated as within the scope of the invention that bores of differing diameter might be preferable in some embodiments. For example, a first fastener (threaded or a unidirectional barbed section) might extend through the bore 330 to connect the spacer block 300 to the manifold block. A second fastener (threaded or a unidirectional barbed section) might extend through an orifice in the PC board to bore 320 to connect the PC board to the spacer block 300. In any of these variations on this embodiment, the spacer block again assists in stabilizing or retaining the PC board to the manifold block.

The first cylindrical portion 344 has a height 353 of about 0.553 inches. The second cylindrical portion 348 has a height 351 of about 0.530 inches. The height 350 of the entire spacer block 300 is preferably about 1.160 inches.

Referring now to FIG. 11, the first cylindrical portion 344 defines an internal bore 320 with an inner diameter 332 that is preferably about 0.390 inches. The second cylindrical portion 348 defines a bore 330 with an inner diameter 331 that is preferably about 0.221 inches. Fins 316 each have a bottom end 317 with a width 357 of about 0.131 inches. Fins 316 are preferably angled from the vertical by an angle 361 of about eleven degrees. The bottom end 317 of each fin 316 is preferably offset from the bottom end 370 by a distance 358 of about 0.250 inches. The transition from inner diameter 332 of bore 320 to the inner diameter 331 of bore 330 might include a taper, however as just noted above, the most preferred version of this embodiment is simply a single bore extending the length 350 of the spacer block 300, having a diameter 331.

Top end 310 is intended to be secured to a PC board (not illustrated in FIGS. 8-11) that preferably rests atop at least a portion of top surface 314 of top end 310 of spacer block 300. With reference to FIG. 11, in the embodiment of FIGS. 8-11, the PC board is preferably secured to the spacer block 400 via a fastener including, but not limited to, a bolt with a securing end including external screw threading that corresponds to the internal threading in a threaded hole in the manifold block (not illustrated in FIGS. 8-11). The bolt is preferably inserted through a hole in the PC board into the bore 320 in top surface 314 of the top end 310 of spacer block 100. The threaded end of the bolt passes all the way through bore 320 and also through bore 330 to the opening on the bottom end 370 of the spacer block 300. The bolt passes through a spacer plate and is installed into the internally threaded hole of the manifold block until contact between the driving head of the bolt and the top surface of the PC board is made.

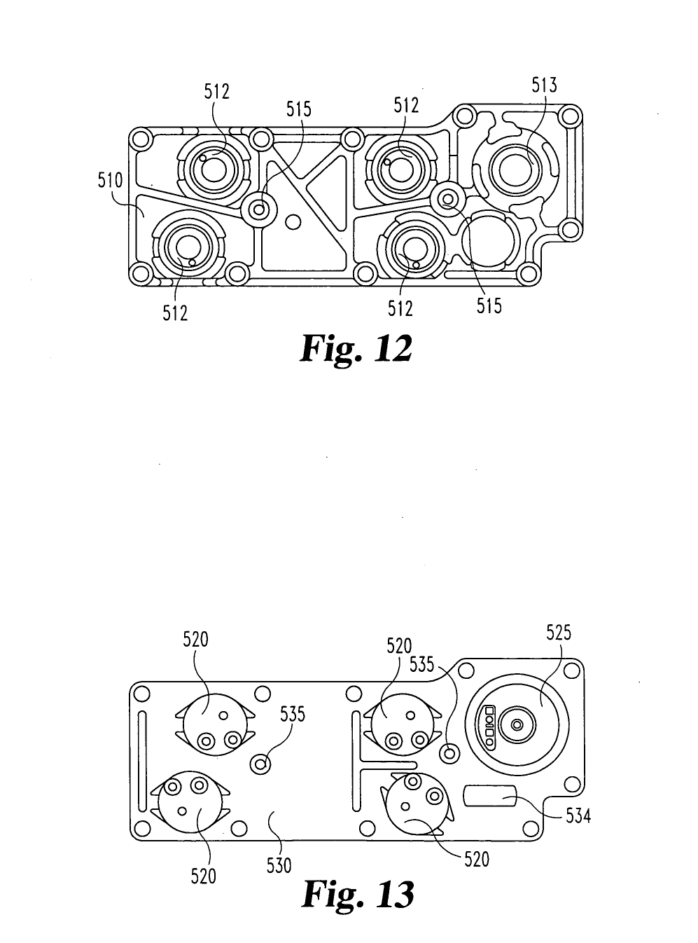

With reference to FIGS. 12-15 there are illustrated aspects of the procedure for assembling the solenoid module 500 of the present invention. The procedure for assembling the module therein makes use of a spacer block 550 that is similar to the previously described embodiment of spacer block 200 of FIGS. 5-7 that included an opening 220 with internal threading 222. However, it is contemplated as within the scope of the invention that the procedure for assembling solenoid module 500 might include any of the wide variations of the embodiments of the spacer blocks 200, 300 or 400 with only minor alterations in the procedure discussed herein.

With reference to FIG. 12 there is illustrated the base manifold 510 of solenoid module 500. Base manifold 510 includes a plurality of solenoid openings 512 that are sized to receive solenoids 520 and one opening 513 sized to receive the variable force solenoid 525. Base manifold 510 further includes an opening for at least a portion of terminal connector 540. Base manifold 510 also includes a plurality of spacer block openings 515, each opening 515 for connection to a spacer block 550. Each spacer block opening 515 preferably includes internal threading that corresponds to either external threading on the spacer block 550 (as with embodiments similar to the spacer blocks 100 or 200) or to threading on a bolt passing through the spacer blocks (for embodiments similar to spacer block 300). It should be understood that it is contemplated as within the scope of the invention that spacer block openings 515 might instead include threads or grooves for securing a unidirectional barbed section of a fastener including the same.

With reference to FIG. 13 there is illustrated a partially assembled solenoid module 500 in which the base manifold component 510 has been combined with a plurality of solenoids and a spacer plate. The plurality of solenoids 520 and the variable force solenoid 525 have been inserted into base manifold 510. The spacer plate 530 is then added over the solenoids to abut the base manifold 510 in one or more locations. Spacer plate 530 has solenoid openings sized such that the spacer plate 530 preferably fits over the various solenoids. The solenoids are preferably secured into the manifold by two tangs that are captured by the spacer plate. Spacer plate 530 includes a terminal connector opening 534 to receive terminal connector 540.

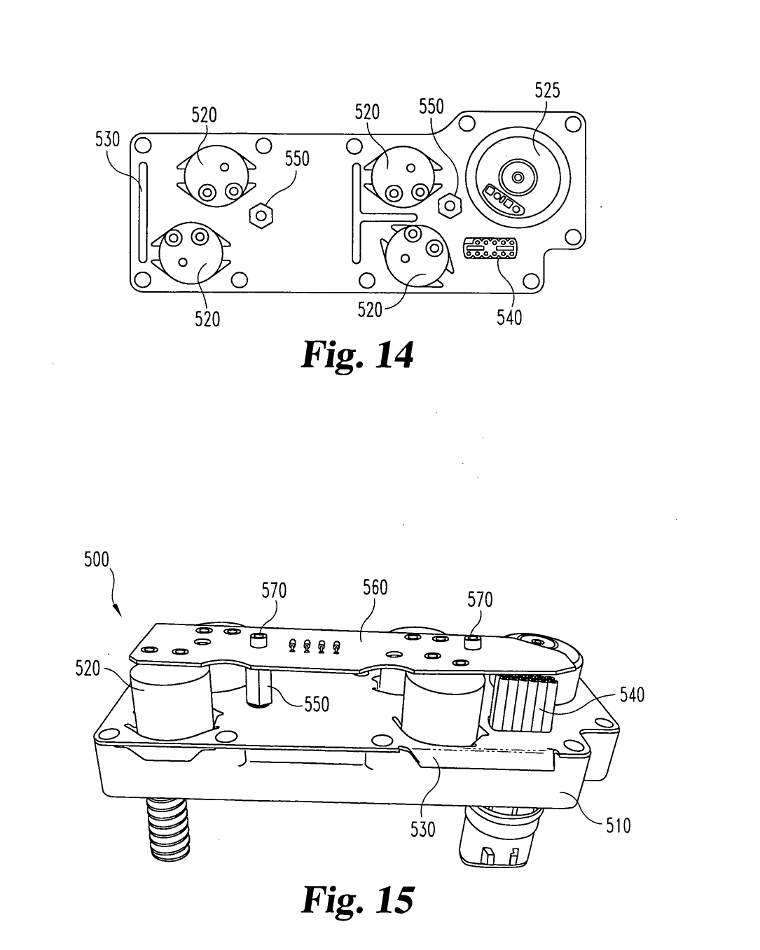

With reference to FIG. 14 there is illustrated a partially assembled solenoid module 500 illustrating the components of FIG. 13 with the addition of the terminal connector 540 and a plurality of spacer blocks 550. As previously mentioned, the illustrated spacer block 550 is similar to the previously described embodiment of spacer block 200 of FIGS. 5-7 that included a top end 210 having an opening 220 with internal threading 222 and a bottom end 270 with an externally threaded portion 276. The spacer blocks 550 each include a bottom end with external threading that is inserted through spacer block opening 535 of spacer plate 530 and is installed into spacer block openings 515 of base manifold 510. The spacer blocks 550 are preferably connected to the base manifold 510 after insertion of the terminal connector 540 through opening 534 of spacer plate 530, however the order of insertion of these two components may be reversed. Similarly the terminal connector 540 may be inserted before or after the spacer plate 530.

With reference to FIG. 15 there is illustrated one embodiment of a fully assembled solenoid module 500. Preferably unencapsulated PC board 560 has been inserted and soldered onto partially assembled module of FIG. 14. After (or before) soldering the electrical connections, a plurality of fasteners 570 are inserted through orifices in preferably unencapsulated PC board 560, and installed into the internally threaded opening at the top end of each spacer block 550.

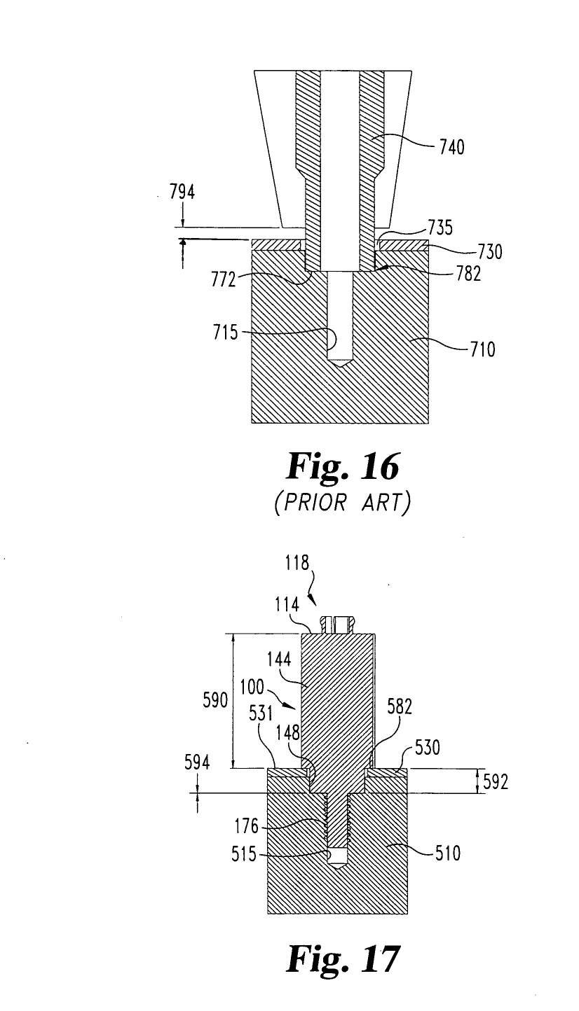

With references to FIGS. 16 and 17, another aspect of the spacer block of the present invention that may be implemented is illustrated. Various embodiments of the spacer block of the present invention may be designed such that the spacer block holds the spacer plate against the base manifold prior to installation into the transmission.

With reference to FIG. 16 there is illustrated a prior art solenoid assembly. The tip 772 of mounting post 740 (part of the overmolded PC board) passes through the opening 735 of spacer plate 730 and contacts the opening 715 of base manifold 710 at contact 782. The mounting post 740, however, does not contact the spacer plate 730 (from the top or in the vertical axis of the solenoid module) even when a fastener (not illustrated) might be installed into hole 715 of base manifold 710. Instead there is a gap or clearance 794 that might be as large as 0.200 inches. Thus, the spacer plate 730 can move (up to 0.200 inches along the vertical axis of the mounting post 740) in the solenoid block module until installation in the transmission. At that time, there are 10 bolts that are secured through the base manifold 710 into the transmission. Upon tightening of these 10 bolts, the manifold 710 and spacer plate 730 are secured together. Since the spacer plate 730 holds the solenoids (not illustrated in FIG. 16) in place via the bent tabs of the spacer plate 730, the solenoids could also move prior to installation.

With reference to FIG. 17, there is illustrated an embodiment of the spacer block of the present in which the spacer block holds the spacer plate against the base manifold prior to installation into the transmission. FIG. 17 is described implementing the embodiment of FIGS. 1-4 wherein like elements are labeled as previously described. It should be understood, however, that it is contemplated as within the scope of the invention that this aspect of the invention is preferably implemented in any of the various embodiments of a spacer block (such as those described in all of FIGS. 1-11). As illustrated in FIG. 17, the spacer block 100 can be implemented in the solenoid module such that the hexagonal portion 144 of the spacer block 100 contacts the top surface 531 of the spacer plate 530, therefore securing the spacer plate 530 and base manifold 510 together. The preferably cylindrical portion 148 is received in the upper part of spacer block opening 515 of base manifold 510. The lower part of spacer block opening 515 preferably includes threading (or grooves) to retain external threading 176 of spacer block 100 (or a unidirectional barb for embodiments of a spacer block including the same).

In one preferred embodiment the spacer block 100 has a hexagonal portion with a length 590 of about 0.980 inches (extending from the top surface 114 of spacer block 100 to the top surface 531 of the spacer plate 530), and the substantially cylindrical portion 148 preferably has a length 592 of about 0.183 inches. Contact occurs at 582 between the hexagonal portion 144 of spacer block 100 and the top surface 531 of spacer plate 530. There is preferably a clearance 594 of about 0.003 inches between the bottom surface of portion 148 and the corresponding surface of spacer block opening 515 in base manifold 510.

It should be understood that it is contemplated as within the scope of the invention that other embodiments could include a “built-in” washer at the end of the hexagonal portion 100 that contacts the spacer plate 530. A separate washer could be used for the same purpose. This aspect of the present invention preferably assists the installer by preventing misalignment of the bolt clearance holes in the spacer plate holes and corresponding manifold holes. It also prevents or minimizes movement of the solenoids. Solenoid movement can put stress on the soldered connections during shipment and handling.

It should be understood that references to top end and bottom end (or first end and second end) are merely terms of convenience used in describing the spacer block(s) and/or solenoid block module of the present invention. Such terms, while in some circumstances explicitly applicable to a preferred orientation during manufacture, are not intended in any way to limit the present invention to any particular orientation of the solenoid block module. In particular, no limitation is intended regarding the orientation of the solenoid block module when affixed to an automatic transmission or internal combustion engine.

It should also be understood that the various embodiments of a spacer block disclosed above may be manufactured from a wide variety of materials known to those of ordinary skill in the art. Examples include polymers, metals, composites, as well as combinations of the same. The spacer block is preferably manufactured from polymers including, but not limited to, Nylon 6/6, Nylon 4/6, or polyimides. In particular, in one preferred embodiment the spacer block is manufactured from about 67% Nylon 6/6 and about 33% Glass Fibers. It should further be understood that all lengths, widths, diameters, and other sizes disclosed herein are exemplary. Absent such dimensions being explicitly claimed, the disclosure of such dimensions is not intended to limit the scope of the present invention.

It should be understood that the spacer blocks of the various embodiments of the present invention preferably include a first end secured to a threaded or grooved hole in the manifold block and a second end secured to the PC board. The first end preferably comprises an externally threaded portion that provides direct connection with the internally threaded hole in the manifold block. The first end may alternatively be of a one direction “barbed” style where the first end can be pushed into the threaded or grooved hole with relative ease, but substantially higher force is required to pull the first end out of the threaded hole in the solenoid block. The first end may not necessarily provide for direct connection between the spacer block and the manifold block depending on the design of the second end.

The second end can be joined to a PC board through numerous connection means as disclosed herein. For example, as previously discussed with reference to FIGS. 5-7 and FIGS. 12-15, the second end might include the use of a threaded fastener connection in which the second end includes an internally threaded hole. A fastener would be inserted through the PC board and tightened, thus securing the PC board. Another connection means includes a second end comprising a male threaded stud that is inserted through a hole in the PC board. A nut would be tightened to the second end, thus securing the PC board. Another connection means might include a design wherein the spacer block is preferably tapered to provide more surface contact at the PC board, and is connected via a passage (preferably a single diameter bore) extending through the length of the spacer block. An example of such a design was previously described with reference to FIGS. 8-11. In the embodiment of FIGS. 8-11 a long bolt is preferably inserted through a hole in the PC board into an opening on the second end of the spacer block all the way to the opening on the first end of the spacer block. The bolt is tightened into the internally threaded hole of the manifold block until contact between the head of the bolt and surface of the PC board is made. Another embodiment of a connection means contemplated as within the scope of the invention is a fastener with a unidirectional barbed section. Such a fastener would be inserted through an orifice in the PC board hole into an internal hole of the spacer block. This internal hole of the spacer block could be threaded or grooved to prevent the fastener from easily being removed. Similarly, the fastener with a unidirectional barbed section could extend all the way through a passage in the spacer block and be retained by a threaded or grooved hole in the base manifold.

The presently preferred embodiment is that illustrated in FIGS. 1-4 wherein the second end includes snap fit means for connecting to the PC board through a bore opening of the PC board. It should be understood that the snap fit that goes into the PC board does not connect it as firmly as a threaded screw joint such as the internal threading present in, for example, the connection means of FIGS. 8-11. However, the snap fit means for connecting the spacer block to the PC board is nonetheless presently believed preferable on the basis of permitting quicker assembly and/or requiring less parts for assembly.

One application of an embodiment of the present invention comprises an apparatus enabling servicing of a solenoid block module (for example, a solenoid block similar to that described in U.S. Pat. No. 4,678,006). It should be understood by those of ordinary skill in the art that it is contemplated as within the scope of the invention that the solenoid block may be rebuilt by any of a number of parties including, but not limited to, at the transmission service shop level or rebuilt by a manufacturer (remanufacturer) that would sell as a rebuilt unit to the service shop. It is understood that rebuilt units will sell for prices less than the cost of a new solenoid block module. For example, a rebuilt unit might sell for as low as $100 depending on the level of servicing within the solenoid block module. These savings are significant to the previously discussed $200-$300 price for a new solenoid block module, a price range generally dependent on the vehicle.

Current commercial products include rebuilding solenoid modules by using old solenoids that have been tested. For example, in the disassembly of 100 used solenoid block modules the rebuild manufacturer is only able to make something less than 100 after all the bad components have been identified and discarded. Another application of the present invention is a rebuilt solenoid block module with either all new solenoids or a combination of new and old solenoids. Various applications of the present invention might permit the disassembly of the same 100 used solenoid block modules to replace the bad solenoids with new ones and now have 100 rebuilt solenoid block modules. Alternatively, it is contemplated as within the scope of the invention to include all new solenoids in the rebuilt solenoid block module.

While the invention has been illustrated and described in detail in the drawings and foregoing description, the same is to be considered as illustrative and not restrictive in character, it being understood that only the preferred embodiments have been shown and described and that all changes and modifications that come within the spirit of the inventions are desired to be protected. It should be understood that while the use of words such as preferable, preferably, preferred or more preferred utilized in the description above indicate that the feature so described may be more desirable, it nonetheless may not be necessary and embodiments lacking the same may be contemplated as within the scope of the invention, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion and/or the entire item unless specifically stated to the contrary.

What is claimed is:

1. A spacer block for stabilizing or mechanically retaining a printed circuit board of a rebuilt solenoid module, the rebuilt solenoid block module further including a manifold block and a spacer plate, the spacer block comprising:
a main body extending between a first end and a second end, the first end including first means for connecting to the manifold block, and wherein the second end includes second means for connecting to the printed circuit board.

2. The spacer block of claim 1, wherein the first means for connecting comprises an external threaded portion extending from the first end of the main body.

3. The spacer block of claim 2, wherein the second means for connecting comprises an internally threaded bore in the second end extending toward the first end, the bore sized to receive a threaded fastener passing through an orifice in the printed circuit board.

4. The spacer block of claim 2, wherein a portion of the main body adjacent the second end has a hexagonal cross section, and wherein a portion of the main body adjacent the first end has a substantially circular cross-section.

5. The spacer block of claim 1, wherein the main body has a length of about 1.160 inches.

6. The spacer block of claim 1, wherein the second means for connecting at is a snap fit means for connecting.

7. The spacer block of claim 6, wherein the snap fit means for connecting includes a plurality of flanges extending from the second end in a direction away from the first end.

8. The spacer block of claim 7, wherein each flange defines a portion of an arc of a circle, the flanges each having a first portion with a first outer diameter adjacent the second end and a second portion with a second outer diameter, the second outer diameter being larger than the first outer diameter.

9. The spacer block of claim 8, wherein the second outer diameter is greater than the first outer diameter by 0.001 to 0.05 inches, and wherein the main body has a length of about 1.160 inches.

10. The spacer block of claim 1, wherein the first means for connecting comprises an external threaded portion extending from the first end of the main body, the second means for connecting comprises an internally threaded bore in the second end extending toward the first end, the bore sized to receive a fastener passing through an orifice in the printed circuit board, wherein the main body has a length of about 1.160 inches.

11. A rebuilt solenoid module, comprising:
a manifold block;
a plurality of solenoids received in a plurality of corresponding solenoid openings in the manifold block, wherein at least one of the solenoids is a new solenoid;
a spacer plate abutting at least a portion of the manifold block, the spacer plate also including a plurality of solenoid openings;
a terminal connector inserted through a terminal connector opening in the spacer plate;
a plurality of spacer blocks, each spacer block having a main body extending between a top end and a bottom end, at least a portion of the bottom end being connected to the manifold block; and
a printed circuit board soldered to at least one electrical connection on each of the plurality of solenoids, the printed circuit board being connected to the top end of at least one of the plurality of spacer blocks.

12. The rebuilt solenoid module of claim 11, wherein the at least one of the plurality of spacer blocks is not integrally formed with other components of the rebuilt solenoid module.

13. The rebuilt solenoid module of claim 11, wherein the printed circuit board is an unencapsulated printed circuit board.

14. The rebuilt solenoid module of claim 13, wherein all of the plurality of solenoids are new solenoids.

15. The rebuilt solenoid module of claim 11, wherein the bottom end of each spacer block includes first means for connecting to the manifold block.

16. The rebuilt solenoid module of claim 15, wherein the first means for connecting to the manifold block comprises a threaded portion extending from the bottom end of the main body.

17. The rebuilt solenoid module of claim 15, wherein the top end of each spacer block includes second means for connecting to the printed circuit board.

18. The rebuilt solenoid module of claim 17, wherein the second means for connecting is a snap fit means for connecting.

19. The rebuilt solenoid module of claim 18, wherein the snap fit means for connecting includes a plurality of flanges extending upward from a top surface of the top end of the spacer block.

20. The rebuilt solenoid module of claim 18, wherein each flange defines a portion of an arc of a circle, the flanges each having a first portion with a first outer diameter adjacent the top surface of the second end and a second portion with a second outer diameter, the second outer diameter being larger than the first outer diameter, the first outer diameter of the flanges of the spacer block is about the same as the diameter of the orifice in the printed circuit board, and wherein the second outer diameter is greater than the first outer diameter by 0.001 to 0.05 inches.

21. The rebuilt solenoid module of claim 17, wherein the second means for connecting comprises a bore in the top end of each spacer block extending through at least a portion of the main body toward the bottom end of each spacer block, the top end of the spacer block and the printed circuit board being connected via a fastener passing through the spacer block orifice in the printed circuit board and inserted into the bore at the top end of the spacer block.

22. The rebuilt solenoid module of claim 11, wherein a portion of the spacer block contacts a top surface of the spacer plate and holds the spacer plate against the manifold block.

23. A rebuilt solenoid module, comprising:
a manifold block;
a plurality of solenoids received in a plurality of corresponding solenoid holes in the manifold block;
a spacer plate contacting at least a portion of the manifold block, the spacer plate also including a plurality of solenoid holes;
a terminal connector inserted through a terminal connector hole in the spacer plate;
a plurality of spacer blocks, each spacer block having a main body extending between a first end and a second end, the first end including first means for connecting the spacer block to the manifold block; and
a printed circuit board soldered to at least one electrical connection on each of the plurality of solenoids, the printed circuit board having a plurality of spacer block orifices, the printed circuit board being connected to a second means for connecting at the second end of each spacer block through the respective one of the plurality of spacer block orifices.

24. The rebuilt solenoid module of claim 23, wherein the printed circuit board is an unencapsulated printed circuit board.

25. The rebuilt solenoid module of claim 24, wherein at least one of the plurality of solenoids is a new solenoid.

26. The rebuilt solenoid module of claim 24, wherein the first means for connecting and the second means for connecting include a single fastener extending through a passage defined between the first end and the second end of each spacer block.

27. The rebuilt solenoid module of claim 26, wherein the fastener is a bolt having an externally threaded end that passes through each spacer block orifice of the unencapsulated printed circuit board and through the second end of the spacer block and out the first end, the externally threaded end of the bolt being installed into a corresponding internally threaded spacer block opening in the manifold block.

28. The rebuilt solenoid module of claim 23, wherein a portion of the spacer block contacts a top surface of the spacer plate and holds the spacer plate against the manifold block.
